(19) United States
(12) Patent Application Publication
(10) Pub. No.: US 2023/0407822 A1
(43) Pub. Date: Dec. 21, 2023

(54) Fuel Ionization Apparatus

(71) Applicant: Chun Ho MAENG, Seoul (KR)

(72) Inventor: Chun Ho MAENG, Seoul (KR)

(21) Appl. No.: 18/030,663

(22) PCT Filed: Oct. 6, 2020
(86) PCT No.: PCT/KR2020/013551

§ 371 Date: Apr. 6, 2023

(51) Int. Cl. F02M 27/04; H03K 3/57

(52) U.S. Cl. CPC F02M 27/04; F02M 2027/047; H03K 3/57

(57) ABSTRACT

A fuel ionization apparatus according to the present Invention comprises: a first electrode unit and a second electrode unit provided in a fuel supply pipe through which fuel flows; and a pulse generation unit for applying electricity (pulses) of different polarities to the first electrode unit and the second electrode unit, wherein the first electrode unit and the second electrode unit are provided to be separated from each other so as not to overlap in the longitudinal direction of the fuel supply pipe, and can form an electric field over a predetermined length range of the fuel supply pipe.

### FIELD

The present invention relates to a fuel ionization apparatus using an electric field.

More specifically, the present invention relates to a fuel ionization apparatus which forms an electric field over a predetermined length range of a fuel supply pipe supplying a combustible fluid, that is, a fuel, to various internal combustion engines such as a vehicle engine.

### BACKGROUND

In general, an internal combustion engine such as a diesel engine or a gasoline engine uses a fossil fuel to obtain power (or an engine output). For example, the diesel engine uses light oil or heavy oil as a fuel, and the gasoline engine uses gasoline as a fuel.

These fossil fuels are classified depending on a boiling point range when crude oil is fractionally distilled. Gasoline is a liquid flammable fuel with a boiling point range of 30 to 200° C., light oil is a fuel whose boiling point is 250 to 350° C., and heavy oil is liquid oil remaining after distilling LPG, gasoline, kerosene and light oil from crude oil.

Any fossil fuel is not composed of a single molecule, but is composed in the form of a mixture of various hydrocarbons. Hydrocarbons constituting a fossil fuel include ethylenic hydrocarbons composed of chain bonds, such as ethylene, propylene and butane, and aromatic hydrocarbons having a benzene ring, such as benzene, toluene and xylene. All of these hydrocarbons are unsaturated hydrocarbons, react with hydrogen and ionize or decompose under a magnetic field.

The internal combustion engine using the fossil fuel emits oxides such as carbon monoxide or sulfur dioxide, although there is more or less a difference during operation. Oxides generated by combustion in the internal combustion engine not only pollute the atmosphere, but also are very harmful to the human body. Therefore, many studies have been conducted to reduce the emission amount thereof as much as possible.

As representative technologies currently put into practical use, a fuel efficiency improvement technology that indirectly reduces a pollutant emission amount by burning the fuel close to complete combustion by increasing combustion efficiency in a combustion chamber and an exhaust gas reduction technology that directly reduces a pollutant emission amount by reducing and removing pollutants generated by combustion in the combustion chamber, using a catalytic device installed in an exhaust pipe, have been developed.

Of them, the fuel efficiency improvement technology is relatively more effective than the exhaust gas reduction technology because the fuel efficiency improvement technology may not only save the fuel by increasing the thermal efficiency of the internal combustion engine but also improve the output of the engine.

As a representative fuel efficiency improvement technology that has been currently put into practical use and whose effectiveness has been recognized, there is disclosed a fuel saving device which improves fuel efficiency by increasing combustion efficiency in the combustion chamber by ionizing the fuel supplied to the combustion chamber using a high-frequency magnetic field of a magnet or an electromagnet.

Such a fuel saving device using a magnetic field employs a principle that, when a magnetic field is applied to the fuel for at least a predetermined time, the magnetic dipoles of fuel particles vibrate under influence of the magnetic field, whereby the internal energy of the fuel particles increases and the fuel particles are ionized.

However, the method of ionizing the fuel using a high-frequency magnetic field of a magnet or an electromagnet may encounter a problem in that a fuel efficiency improvement effect is small and a harmful exhaust gas reduction effect is insignificant as well.

In addition, a problem may arise in that, due to a crack by vibration at a part where a fuel activation pipe and a fuel pipe are coupled, the risk of fire by leakage of the fuel increases.

As a result of searching for the prior art related with the present invention, a number of patent documents have been found, and some of them are introduced as follows.

In KR10-1997-0070514 A, there is disclosed a fuel saving device including a fuel activation pipe which is connected to a fuel system; a plurality of magnet rings which are arranged adjacent to the same magnetic poles on the outer circumferential surface of the fuel activation pipe; and a cover which surrounds and protects the outsides of the plurality of magnet rings, wherein a continuous high-frequency magnetic field having an entirely uniform magnetic flux density is formed inside and outside the magnet rings to cause a fuel to be magnetized to a state capable of being easily ionized, thereby atomizing the fuel very finely so that combustion close to complete combustion is performed.

In KR10-1997-0075298 A, there is disclosed a fuel activation device for a vehicle. In the fuel activation device for a vehicle, a coupling pipe including the fuel activation device is inserted and installed over a predetermined section of a fuel introduction pipe which connects a fuel pump and a fuel injector, a center rod is inserted and fixed inside the coupling pipe in a lengthwise direction so that a vortex phenomenon may occur in a fuel passing through the coupling pipe, a fuel conduit is spirally wound on the outer circumferential surface of the center rod to be installed to give rotational force to the fuel passing through the center rod, a cylindrical bobbin is inserted and installed on the outer circumferential surface of the coupling pipe, a coil capable of applying electric power is wound on the outer cylindrical portion of the bobbin, and an outer case which surrounds the outside of the bobbin and supports and fixes the coupling pipe is configured to form the outside of the fuel activation device, wherein, since the fuel supplied to the fuel injector through the fuel introduction pipe is injected in a state in which atomization is promoted by a vortex and a magnetic field, the degree of dispersion is increased by atomization of fuel particles, and incomplete combustion in a cylinder is almost eliminated, whereby not only output of an engine is improved but also discharge of an exhaust gas due to incomplete combustion is maximally suppressed.

In KR20-0335942 Y1, there is disclosed a fuel ionization apparatus including a cylindrical mesh cylinder made of a mesh to have a predetermined diameter; a lower cover coupled to one opening of the mesh cylinder; a flange coupler having one end fixedly coupled to the other opening of the mesh cylinder and the other end which is formed with a thread; an upper cover formed with a threaded hole at a center and formed with a thread on an inner periphery to be threadedly coupled to the flange coupler; and a chain having both ends to which a latch ring fitted into and coupled to an oil cap of a fuel tank and a lug formed with a hole at a center are coupled, the lug being screwed into the threaded hole formed at the center of the upper cover, wherein a ceramic catalyst including tourmaline is contained inside the mesh cylinder. A conductive ceramic catalyst which reduces molecular grouping of the fuel and lowers viscosity and density of the fuel to convert the fuel into an active state so as to make combustion more smooth is charged in the fuel ionization apparatus.

KR10-1512281 B1 discloses a fuel saving and emission reduction apparatus having fuel atomization and ionization means, disposed by being connected to a fuel line installed to supply a fuel to an internal combustion engine used in automobiles and ships, suitable for preheating the fuel supplied to the internal combustion engine and contributing to complete combustion of the fuel by atomizing and ionizing the fuel. The apparatus includes a fuel line disposed by being connected to one end of the internal combustion engine to supply fuel to the internal combustion engine; a fuel flow rate sensor disposed on the fuel line to sense a flow rate of the fuel supplied to the internal combustion engine; a preheating unit disposed at one side of the fuel flow sensor to cover the fuel line and installed to preheat the fuel flowing inside the fuel line to 40 to 80° C.; an ultrasonic vibration unit installed at one side of the preheating unit with an interval, having both sides to which the fuel line is connected to be supplied with the fuel from one side, and including disposed therein an ultrasonic vibrator to atomize the fuel supplied to the inside thereof; a vortex hole installed on one side of the ultrasonic vibration unit to be supplied, through the fuel line, with the fuel atomized by the ultrasonic vibration unit, formed in a cylindrical shape having a spiral vortex groove recessed inward from an outer circumference, and disposed inside the fuel line; a transmission unit configured to generate a triangular wave corresponding to the flow rate of the fuel received from the fuel flow rate sensor; an amplification unit connected to the transmission unit, and configured to receive the triangular wave, shape and convert the triangular wave transmitted from the transmission unit into a high-frequency sine wave and output the sine wave; and a pair of winding cases installed on the fuel line on both sides, respectively, of the vortex hole, each winding case being formed to have a semicircular cross-sectional shape to surround the outer circumferential surface of the fuel line and being formed, on the outer circumferential surface, with a spirally recessed winding groove, wherein a radiation coil whose both sides are connected to the amplification unit to receive the sine wave and which is wound in the winding groove to radiate the sine wave supplied from the amplification unit is disposed in the winding groove of the winding case, a pair of output units each having a first case and a pair of magnets are disposed on the outer circumferential surfaces of the winding case and the radiation coil, the first case being formed to have a semicircular cross-sectional shape and disposed to surround the outer circumferential surfaces of the winding case and the radiation coil, the pair of magnets being disposed between the output units on the fuel line, each magnet being formed to have a semicircular sectional shape to surround the outer circumferential surface of the fuel line, the pair of magnets being formed to have opposite polarities to supply magnetic force to the fuel passing through the inside of the fuel line, a pair of ionization units each having a second case are formed on the outer circumferential surfaces of the magnets, each ionization unit being formed to have a semicircular sectional shape to surround the outer circumferential surface of the magnet, each ionization unit having at a distal end thereof a projection which projects inward to surround both ends of each magnet, and a cylindrical pressurizer is inserted between the ultrasonic vibration unit and the vortex hole inside the fuel line and is formed therein a plurality of holes.

Japanese Patent Application Publication No. Sho 58-140462 discloses positive and negative electrodes 16 to 19 and 24 to 27 installed on fuel injection pipes. The positive electrodes and the negative electrodes are disposed to be opposed to each other with the fuel injection pipes interposed therebetween at the same positions in the lengthwise direction of the fuel injection pipes. According to this document, a problem may arise in that it is difficult for a fuel to be ionized or atomized to the extent that it is possible to improve the efficiency of an internal combustion engine. In addition, this document discloses, a spark is likely to occur since the distance between each positive electrode and each negative electrode is narrow, and various safety accidents may occur due to the spark. In particular, in an environment where a situation in which the positive electrodes and the negative electrodes are reversed with a short period is required, sparks are likely to frequently occur. Therefore, various safety measures for preventing occurrence of sparks should be sufficiently defined, which makes practical application difficult.

### SUMMARY

The present invention has been made in an effort to solve the problems of the prior art, and an object of the present invention is to provide a fuel ionization apparatus or fuel ionization method using an electric field, capable of not only contributing to complete combustion of a fuel but also improving both fuel efficiency of an internal combustion engine and output of the engine, by applying power in the form of pulse waves to positive (+)/negative (−) electrodes installed with an interval on a fuel supply pipe to form an electric field over a predetermined length range of the fuel supply pipe so that, by the action of the electric field, the fuel flowing along the internal flow path of the fuel supply pipe is ionized or atomized.

It is to be understood that technical objects to be achieved by the present invention are not limited to the aforementioned technical objects and other technical objects which are not mentioned herein will be apparent from the following description to one of ordinary skill in the art to which the present invention pertains.

In order to achieve the above object, a fuel ionization method using an electric field according to the present invention is characterized in that a first electrode unit and a second electrode unit are installed with a predetermined interval therebetween in a lengthwise direction of a fuel supply pipe which supplies a fuel to fuel distribution means (e.g., a common rail or a fuel distributor) including a plurality of injectors (or fuel injection nozzles), and by using a pulse generation unit, power is supplied and cut off with respect to the first electrode unit and the second electrode unit with a predetermined time interval, so that an electric field is formed over a predetermined length range of the fuel supply pipe and by action of the electric field, the fuel flowing along the fuel supply pipe is supplied to the fuel distribution means in an ionized or atomized state to be injected through the injectors.

The pulse generation unit adopted in the fuel ionization method using an electric field according to the present invention is characterized in that it is a pulse generation unit which is able to generate and apply a pulse of 50 to 2,000 Hz, preferably, 50 to 500 Hz.

A fuel ionization apparatus using an electric field according to the present invention is characterized in that it includes fuel distribution means including a plurality of injectors which inject a fuel into an engine; a fuel supply pipe connected at one end thereof to the fuel distribution means to supply the fuel to the fuel distribution means; electric field generation means configured by a first electrode unit and a second electrode unit installed with a predetermined interval therebetween to generate an electric field over a predetermined length range of the fuel supply pipe; and a pulse generation unit including output parts which are connected to the first electrode unit and the second electrode unit, respectively, to apply or cut off power with a predetermined time interval.

The fuel ionization apparatus using an electric field according to the present invention is characterized in that, in order to ensure that a current does not flow between the first electrode unit and the second electrode unit, the fuel supply pipe and the electrode units are insulated from each other.

The pulse generation unit adopted in the fuel ionization apparatus using an electric field according to the present invention is characterized in that it is a pulse generation unit which is able to generate a pulse of 50 to 2,000 Hz, preferably, 50 to 500 Hz.

Power in the fuel ionization apparatus using an electric field according to the present invention is characterized in that it is power of 12 to 24V and 10 to 15A.

A fuel ionization apparatus according to the present invention may include a first electrode unit and a second electrode unit installed on a fuel supply pipe through which a fuel flows; and a pulse generation unit configured to apply electricity of different polarities to the first electrode unit and the second electrode unit.

The first electrode unit and the second electrode unit are installed to be separated from each other not to overlap in a lengthwise direction of the fuel supply pipe, and are able to form an electric field over a predetermined length range of the fuel supply pipe.

A fuel ionization apparatus of the present invention may use a first electrode unit, a second electrode unit and a pulse generation unit, thereby supplying charges of different polarities to a first position and a second position separated from each other in a lengthwise direction of a fuel supply pipe and charging the first position and the second position.

By the first electrode unit and the second electrode unit, first lines of electric force coming out of the first position and entering the second position may be formed, or second lines of electric force coming out of the second position and entering the first position may be formed.

When a fuel passing through an electric field in which the first lines of electric force or second lines of electric force are formed goes through an electric field forming area, the cluster bonding structure of the fuel may unravel, and fuel molecules may be instantaneously ionized to be atomized and may be aligned in the direction of lines of electric force. Due to this fact, the possibility of bonding with air or oxygen is improved, the combustion efficiency of the fuel is increased, and both fuel efficiency and output of an internal combustion engine connected to the fuel supply pipe may be improved.

According to the present invention, the first electrode unit and the second electrode unit may be installed on the outer circumferential surface of the fuel supply pipe. The first electrode unit and the second electrode unit may be installed to be separated from each other in the lengthwise direction of the fuel supply pipe. A separation distance may be larger than the outer diameter of the fuel supply pipe. As a result, a sufficient physical distance at which a spark does not occur may be provided between the first electrode unit and the second electrode unit. Therefore, according to the present invention, it is possible to prevent a device failure, an explosion accident and a fire accident by a spark.

According to the present invention, it is possible to provide various electric sources without worrying about occurrence of a spark. Therefore, the pulse generation unit may provide, to the respective electrode units, electric sources having optimum voltage values, current values and frequencies that greatly improve the ionization of the fuel and the atomization of fuel molecules.

According to the present invention, since a positive electrode and a negative electrode are charged at different positions in the lengthwise direction of the fuel supply pipe, an electric field area having a length sufficient for ionization and atomization may be formed. As a result, according to the present invention, ionization of the fuel flowing along the fuel supply pipe and atomization of fuel molecules may be improved.

According to the fuel ionization apparatus of the present invention, a third electrode which is maintained to have a constant polarity may be additionally defined. A first position, a second position and a third position may be defined in order from upstream to downstream of the fuel supply pipe. Alternatively, a third position, a second position and a first position may be defined in order from upstream to downstream of the fuel supply pipe.

The first electrode unit may charge the first position to a first polarity. The second electrode unit may charge the second position to a second polarity. The third electrode unit may charge the third position to a third polarity. According to a present embodiment, an electric field area in which force that electromagnetically compresses or pulls and stretches the fuel passing between the second position and the third position may be additionally formed. An electric field area formed between the first position and the second position may cause a state in which fuel molecules are spread, and an electric field area formed between the second position and the third position may maintain the state in which fuel molecules are spread. According to the present invention, a large surface area over which the fuel is likely to burn may be exposed for an internal combustion engine.

In the fuel ionization method and fuel ionization apparatus using an electric field of the present invention, power in the form of a pulse wave is applied to electric field generation means installed on the fuel supply pipe, and thus, an electric field or an electromagnetic field is formed over a predetermined length range of the fuel supply pipe. Therefore, as molecules of various hydrocarbons composing the fuel are ionized or atomized by the electric field or the electromagnetic field, combustion close to complete combustion may be achieved, and accordingly, combustion efficiency of the fuel may be improved and at the same time both fuel efficiency and output of an engine may be improved.

According to the fuel ionization method and fuel ionization apparatus using an electric field according to the present invention, as hydrocarbons composing the fuel are ionized and atomized, the fuel may burn close to complete combustion in the engine, and accordingly, it is possible to prevent environmental pollution due to emission of incomplete combustion gas.

According to the fuel ionization method and fuel ionization apparatus using an electric field according to the present invention, as power in the form of a pulse is periodically applied from the pulse generation unit to the electric field generation means, the generation and extinction of an electric field or an electromagnetic field are repeated to apply impact on fuel molecules. Due to this fact, as chain bonds or benzene bonds of hydrocarbon molecules are broken, fuel particles are easily ionized or atomized.

### BRIEF DESCRIPTION OF DRAWINGS

FIG. 1 is a schematic view of a fuel ionization apparatus using an electric field in accordance with the present invention.

FIG. 2 is a detailed view of electric field generation means which is a main part of the present invention.

FIG. 3 is a circuit diagram of a pulse generation unit which is a main part of the present invention.

FIG. 4 is a schematic view illustrating another fuel ionization apparatus of the present invention.

### DESCRIPTION

Hereinafter, embodiments according to the present invention will be described in detail with reference to the accompanying drawings. It should be noted that the drawings are not to precise scale and may be exaggerated in thicknesses of sizes or shapes of components for descriptive convenience and clarity only. Furthermore, the terms specifically defined in consideration of the construction and function of the present invention may be changed according to the intention of users or operators or the practice. Definition of the terms should be made according to the overall disclosures set forth herein.

A fuel ionization apparatus or a fuel ionization method in accordance with the present invention may contribute to ionization of a fuel or atomization of fuel molecules by using a first electrode unit 11, a second electrode unit 12 and a pulse generation unit 15.

The fuel ionization apparatus illustrated in the drawings may include the first electrode unit 11 and the second electrode unit 12 installed on a fuel supply pipe 20 through which the fuel flows. The fuel ionization apparatus may include the pulse generation unit 15 to control an electrical signal to be supplied to each electrode unit.

The pulse generation unit 15 may apply electricity of different polarities to the first electrode unit 11 and the second electrode unit 12. For example, the pulse generation unit 15 may apply positive (+) electricity to the first electrode unit 11 and apply negative (−) electricity to the second electrode unit 12. Alternatively, the pulse generation unit 15 may apply negative (−) electricity to the first electrode unit 11 and apply positive (+) electricity to the second electrode unit 12.

The first electrode unit 11 and the second electrode unit 12 may be installed to be separated from each other so as not to overlap in the lengthwise direction of the fuel supply pipe 20. According to the present invention, it is possible to sufficiently secure an interval between the first electrode unit 11 and the second electrode unit 12 within a range in which a spark does not occur.

In addition, an electric field may be formed by the first electrode unit 11 and the second electrode unit 12 over a predetermined length range extending in not the widthwise direction but the lengthwise direction of the fuel supply pipe 20. An area in which the fuel flowing through the fuel supply pipe 20 is influenced by the electric field may extend in not the widthwise direction but the lengthwise direction of the fuel supply pipe 20. The length of the area of the electric field through which the fuel passes may be sufficiently secured. As the fuel passes through the electric field of the sufficient length, the fuel may be reliably ionized or atomized.

When the fuel flows from a first position toward a second position in the fuel supply pipe 20, the first position may be charged to a first polarity by the first electrode unit 11. The second position may be charged to a second polarity by the second electrode unit 12. The electric field which applies electrostatic force to the fuel may be formed between the first position and the second position.

Each of the first position and the second position may be a part of the inner circumferential surface of the fuel supply pipe 20 which comes into face-to-face contact with the fuel. In view of the flow of the fuel, the first position may be disposed upstream of the second position. Of course, the second position may be disposed upstream of the first position.

The first electrode unit 11 may charge the first position to the first polarity using an electric source inputted from the pulse generation unit 15.

The second electrode unit 12 may charge the second position to the second polarity using an electric source inputted from the pulse generation unit 15. The second polarity may include a polarity opposite to the first polarity. For example, when the first polarity is a positive polarity, the second polarity may be a negative polarity. When the first polarity is a negative polarity, the second polarity may be a positive polarity.

The electric field may be formed between the first position charged to the first polarity by the first electrode unit 11 and the second position charged to the second polarity by the second electrode unit 12. The corresponding electric field may be formed along the flow path of the fuel supply pipe 20 through which the fuel flows.

The first electrode unit 11 and the second electrode unit 12 may be installed to be separated from each other in the lengthwise direction of the fuel supply pipe 20.

The pulse generation unit 15 may apply pulses to the first electrode unit 11 and the second electrode unit 12. Polarities of the first electrode unit 11 and the second electrode unit 12 may be alternately reversed by the pulses (signals).

The first position and the second position that are separated from each other in the lengthwise direction of the fuel supply pipe 20 and sequentially through which the fuel flows may be defined.

The first electrode unit 11 may be installed such that the first polarity is formed at the first position. When the first position is the inner circumferential surface of the fuel supply pipe 20, the first electrode unit 11 may be installed on the outer circumferential surface of the fuel supply pipe 20 which faces away from the first position.

The second electrode unit 12 may be installed such that the second polarity is formed at the second position. When the second position is the inner circumferential surface of the fuel supply pipe 20, the second electrode unit 12 may be installed on the outer circumferential surface of the fuel supply pipe 20 which faces away from the second position.

The pulse generation unit 15 may alternately apply positive electricity and negative electricity to the first electrode unit 11.

When positive electricity is applied to the first electrode unit 11, the pulse generation unit 15 may apply negative electricity to the second electrode unit 12.

When negative electricity is applied to the first electrode unit 11, the pulse generation unit 15 may apply positive electricity to the second electrode unit 12.

According to a present embodiment, a first state in which first lines of electric force coming out of the first position and entering the second position are generated and a second state in which second lines of electric force coming out of the second position and entering the first position are generated may alternately occur. The fuel may be ionized and atomized while passing through the electric field in which the first state and the second state are alternately repeated.

The fuel ionization apparatus in accordance with the present invention may include a third electrode unit 13 to which electricity of a set polarity is applied.

When a first position, a second position and a third position separated from each other in the lengthwise direction of the fuel supply pipe 20 are defined, the first electrode unit 11 may charge the first position to a first polarity. The second electrode unit 12 may charge the second position to a second polarity. The third electrode unit 13 may charge the third position to a third polarity. The third position may be a part of the inner circumferential surface of the fuel supply pipe 20 which comes into face-to-face contact with the fuel. The third position may be formed downstream of the first position and the second position.

The first polarity and the second polarity may be alternately reversed between a positive polarity and a negative polarity by the pulse generation unit 15. The pulse generation unit 15 may provide pulse signals for alternately reversing the first polarity of the first electrode unit 11 and the second polarity of the second electrode unit 12, to the respective electrode units 11 and 12.

The third polarity may be continuously maintained as the positive polarity or may be continuously maintained as the negative polarity. The third electrode unit 13 may be connected to the pulse generation unit 15 or to a separate source to maintain the third polarity. In view of a direction in which the fuel flows, the third position may be formed upstream of the first position and the second position or may be formed downstream of the first position and the second position.

The third electrode unit 13 may charge the third position to the third polarity downstream of the first position and the second position. Alternatively, the third electrode unit 13 may charge the third position to the third polarity upstream of the first position and the second position.

The fuel supply pipe 20 may be connected to fuel distribution means 30 which includes a plurality of injectors 31.

Before being introduced into the fuel distribution means 30, the fuel may pass through an electric field which is formed on the fuel supply pipe 20 due to the presence of the first electrode unit 11 and the second electrode unit 12.

The first electrode unit 11, the second electrode unit 12 and the third electrode unit 13 may be installed in close contact with the outer circumferential surface of the fuel supply pipe 20. An insulation covering 21 may be installed between each electrode unit and the fuel supply pipe 20 to prevent a current of each electrode unit from flowing to the fuel supply tube 20.

In a high voltage pulse generator as a device in which an automobile igniter coil circuit (distributor) and a PWM pulse generator are combined, when a violent chemical reaction and molecular ionization are possible by an induced voltage, before intake air reaches a combustion chamber, ozone and nitrogen oxides are highly likely to be generated by bonding of the intake air with oxygen molecules or bonding of nitrogen molecules and oxygen molecules.

An ion means that a molecule or an atom is charged.

The number of protons in an atom does not change by an ordinary chemical change, but the number of electrons negatively charged may decrease or increase. For this reason, when an atom loses an electron, the atom is positively charged, and when an atom gains an electron, the atom is negatively charged. An ion which is positively charged is called a cation, and an ion which is negatively charged is called an anion.

In a fuel molecule, electrons are attracted toward a nucleus while orbiting around the nucleus, and the nucleus is at the center of an electron orbit. Therefore, due to the bonding force between molecules, during combustion, the fuel burned, with fuel particles not actively interacting with oxygen, enters exhaust gas, thereby causing incomplete combustion.

When a hydrocarbon fuel (methane molecules) is burned, hydrogen atoms are oxidized first. Carbon atoms are then successively burned. However, since hydrogen atoms are oxidized first in a combustion process, a substantially short combustion time is given to carbon atoms. Thus, a part of carbon is only partially oxidized due to the short combustion time. Due to this fact, incomplete combustion occurs. Although oxygen easily bonds with hydrogen, bonding reaction between oxygen and carbon is insufficient. For example, coal dust burns faster than a coal lump.

By applying the fuel ionization apparatus by an electric field to the fuel supply pipe 20 corresponding to a fuel inlet line, it is possible to reduce harmful exhaust gases such as carbon monoxide with optimal efficiency.

When an electric field is applied (a plus (+) electric field and a minus (−) electric field are simultaneously applied) around the fuel inlet line, chains of a cluster of molecules unravel, and fuel molecules that have agglomerated are aligned to bond with more oxygen molecules, by which combustion efficiency of the fuel may be improved.

An electric field is a vector field that surrounds charges and applies force to other charges to attract or repel the other charges. An electric field may be generated by charges, or may be generated by a time-varying magnetic field. An electric field is important in many fields of physics, and is used practically in electrical technology.

A PWM (pulse width modulation) signal is a way of generating a digital source into an analog signal. The PWM signal as a signal having two main components of a duty cycle and a frequency is used in a variety of control applications. The main use of the PWM signal is to control a DC motor, but the PWM signal may also be used to control mechanical parts such as a valve, a pump, a hydraulic device, a robot and an RC car.

A square wave pulse signal generated by pulse width modulation (PWM) may be transferred to a semiconductor drive. The drive may process the pulse signal and transfer the processed pulse signal to a PWM DIR (Arduino).

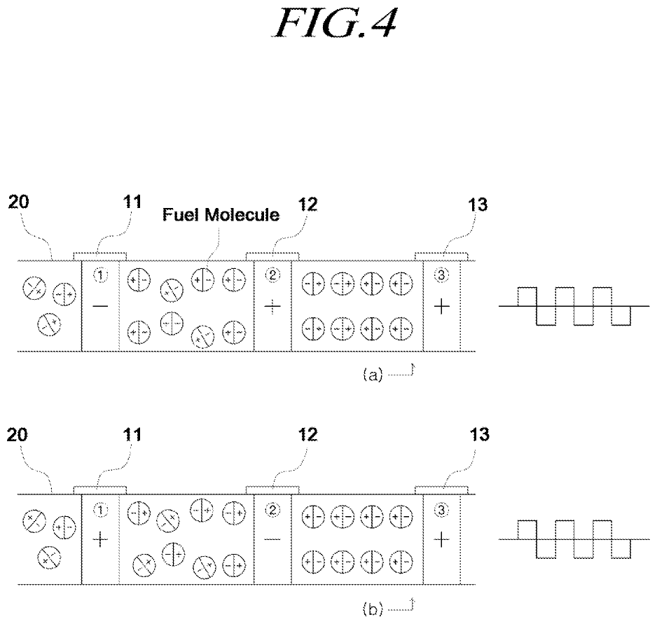

The PWM DIR may control a high voltage and a current generated by an inverter, using the plus (+) signal or the minus (−) signal of a pulse waveform. The PWM DIR may generate an electric field by causing positive electricity and negative electricity of a pulse waveform to simultaneously flow as shown in (a) and (b) of FIG. 4.

For example, the pulse generation unit 15 may simultaneously supply minus electricity to any one of the first electrode unit 11 and the second electrode unit 12 through which plus electricity has flown and plus electricity to the other through which minus electricity has flown, by reversing positions. When one cycle (period) of a pulse is completed, the positions of polarities of an electric field are reversed back and forth twice. In this way, force applied to molecules by an instantaneous electric field position change is considered to be absolute for molecular vibration and ionization.

The third electrode unit 13 may constantly maintain not a pulse waveform but plus electricity without changing positions of polarities. As states of molecules ionized and spread by the first electrode unit 11 and the second electrode unit 12 are maintained by the third electrode unit 13, fuel molecules may flow along the fuel supply pipe 20. The completion of such a pulse cycle of changing polarities has technically required long-time research and experiments, but the present applicant (inventor) has completed the pulse cycle and has applied the pulse cycle to the present invention.

According to the present invention, when the fuel flows through the fuel supply pipe 20, fuel molecules may be ionized to temporarily convert the molecules into a positive ion state. Fuel combustion in this state is much more efficient, and carbon monoxide emission is reduced. As a device for directly exposing a hydrocarbon-based fuel to an electric field, copper plates (respective electrode units) may be mounted to a copper pipe (the fuel supply pipe 20) with insulators interposed therebetween while maintaining a predetermined interval on a fuel line. The electric field generated by simultaneously supplying pulsed electricity by connecting the plus pulse signal and the minus pulse signal of a pulse waveform to the copper pipe as a voltage overcurrent exerts an influence on the polarization of carbon molecules in the fuel and spreads the molecules, exposing large surface areas that are easy to burn.

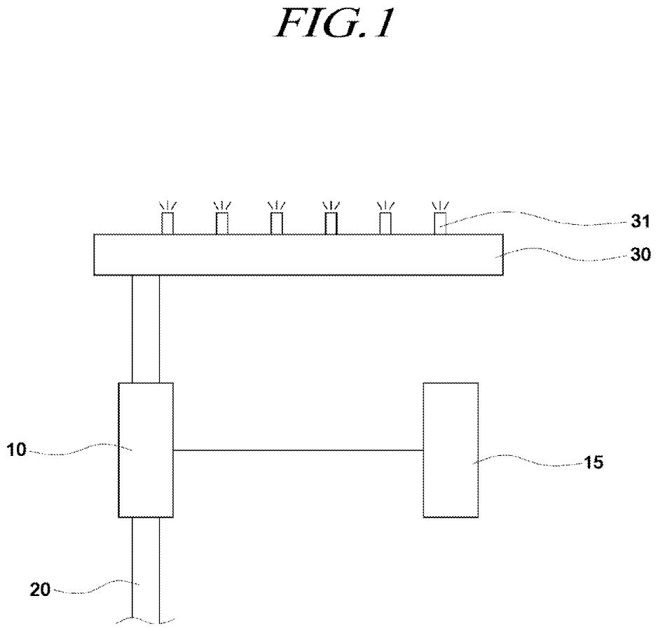

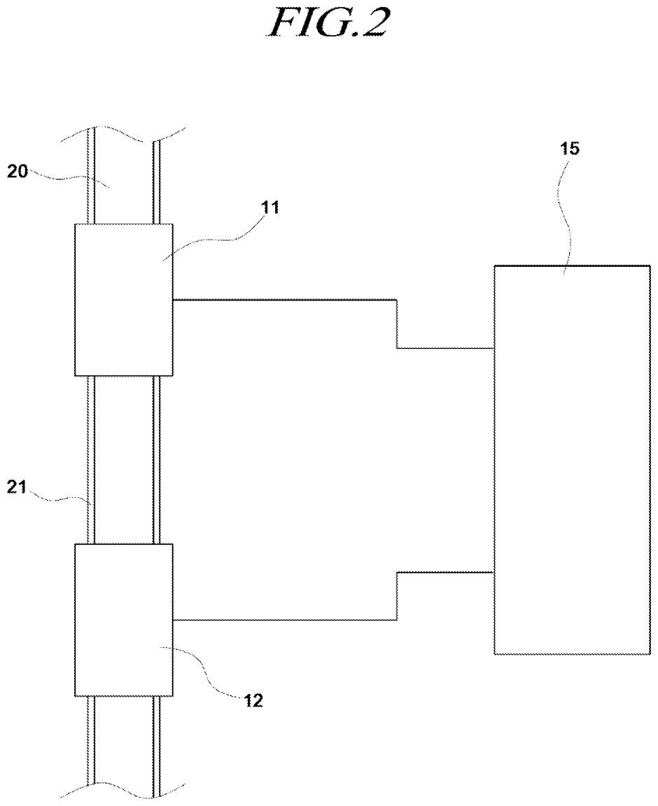

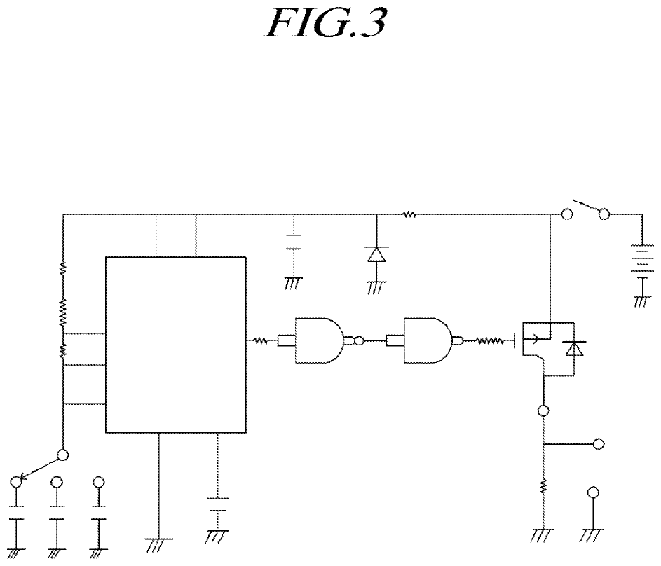

As illustrated in FIGS. 1 to 3, a fuel ionization method and a fuel ionization apparatus using an electric field in accordance with the present invention are characterized in that they are configured such that a first electrode unit 11 and a second electrode unit 12 are respectively installed with a predetermined interval therebetween in a lengthwise direction of a fuel supply pipe 20 which supplies a fuel to fuel distribution means 30 including a plurality of injectors 31, and through a pulse generation unit 15, power (pulse) is supplied and cut off with respect to the first electrode unit 11 and the second electrode unit 12 with a predetermined time interval, so that an electric field is formed over a predetermined length range of the fuel supply pipe 20 and by the electric field, the fuel flowing along the fuel supply pipe 20 is supplied to the fuel distribution means 30 in an ionized or atomized state to be injected into a combustion chamber of an internal combustion engine through the injectors 31.

The fuel distribution means 30 is a common rail in the case of a diesel engine and a fuel distributor in the case of a gasoline engine.

The pulse generation unit 15 generates a pulse of 50 to 2,000 Hz, preferably, 50 to 500 Hz, and supplies the pulse to the first electrode unit 11 and the second electrode unit 12.

Describing in more detail the configuration of the fuel ionization apparatus using an electric field in accordance with the present invention, the fuel ionization apparatus includes fuel distribution means 30 including a plurality of injectors 31 which inject a fuel into an engine; a fuel supply pipe 20 connected at one end thereof to the fuel distribution means 30 to supply the fuel to the fuel distribution means 30; electric field generation means 10 configured by a first electrode unit 11 and a second electrode unit 12 installed outside the fuel supply pipe 20 with a predetermined interval therebetween to generate an electric field when pulsed power is applied; and a pulse generation unit 15 including output parts which are connected to the first electrode unit 11 and the second electrode unit 12, respectively, to apply or cut off pulses with a predetermined time interval.

In order to ensure that a current does not flow between the first electrode unit 11 and the second electrode unit 12, an insulation covering 21 is interposed between the fuel supply pipe 20 and the electrode units 11 and 12. However, in the case where the fuel supply pipe 20 is a supply pipe made of a nonconductor such as plastic, the insulation covering 21 may be omitted.

The first electrode unit 11 and the second electrode unit 12 are configured by, for example, copper tubes having a thickness of 3 to 5 mm and a length of about 30 mm, and are installed so that an interval between the first electrode unit 11 and the second electrode unit 12 formed in a lengthwise direction of the fuel supply pipe 20 is 3 to 25 mm, preferably, 5 to 10 mm. The interval between the first electrode unit 11 and the second electrode unit 12 is related with the generation and intensity (electric field strength) of an electric field (or an electromagnetic field) formed over a predetermined length range in the lengthwise direction of the fuel supply pipe 20. According to repeated experiments by the present applicant, setting the interval to a range of 3 to 25 mm, preferably, 5 to 10 mm, showed the best effects.

The first electrode unit 11 and the second electrode unit 12 are not limited to the above configuration, and may have a different thickness and a different length as the occasion demands. Instead of the copper tubes, thin copper plates may be wrapped around the outer surface of the fuel supply pipe 20.

The pulse generation unit 15 is supplied with power of 12 to 24V and 10 to 15A, for example, from a vehicle battery or through a separate booster, and generates a pulse of 50 to 2,000 Hz, preferably, 50 to 500 Hz and applies the pulse to first electrode unit 11 and the second electrode unit 12.

After the fuel in a fuel tank (not illustrated) is compressed by a fuel pump, the fuel is supplied to the fuel distribution means 30 through the fuel supply pipe 20, and is injected into a combustion chamber of the engine through the injectors 31 installed in the fuel distribution means 30. When electricity is supplied (power is applied) to the first electrode unit 11 and the second electrode unit 12 of the electric field generation means 10 installed on the fuel supply pipe 20, an electric field is formed between the first electrode unit 11 and the second electrode unit 11. As a magnetic field is formed in a direction perpendicular to the flow direction of the fuel by the electric field, bonds of various hydrocarbons forming fuel molecules are broken to be divided into carbon and hydrogen or are ionized. In addition, since the pulse generation unit 15 applies pulses to the first electrode unit 11 and the second electrode unit 12, the generation and extinction of an electric field are repeated in a very short time, and as a result, impact is applied to various hydrocarbons forming fuel molecules (or fuel particles). Accordingly, as chain bonds or benzene bonds of various hydrocarbons are broken, the size of fuel molecules (or particles) is reduced.

According to the fuel ionization method and fuel ionization apparatus using an electric field in accordance with the present invention, configured as described above, as an electric field is formed over a predetermined range of a fuel supply pipe through which a fuel flows along an internal flow path, fuel molecules influenced by the electric field are ionized and atomized, whereby combustion close to complete combustion may be achieved and as a result, emission of an unburned fuel or emission (or the emission amount) of pollutants due to incomplete combustion may be reduced, simultaneously accomplishing improvement in fuel efficiency of an engine and increase in output of the engine.

Although embodiments according to the present invention have been described above, the embodiments are only for illustrative purposes, and those skilled in the art will appreciate that various modifications and other equivalent embodiments are possible without departing from the scope and spirit of the present invention as defined in the accompanying claims. Thus, the true technical scope of protection of the present invention should be defined by the appended claims.

1. A fuel ionization apparatus comprising:
a first electrode unit and a second electrode unit installed on a fuel supply pipe through which a fuel flows; and
a pulse generation unit configured to apply electricity (pulse) so that the first electrode unit and the second electrode unit become a positive electrode and a negative electrode having different polarities from each other,
wherein the first electrode unit and the second electrode unit are installed to be separated from each other in a lengthwise direction of the fuel supply pipe, and
wherein, as electricity (pulse) is periodically applied to the first electrode unit and the second electrode unit from the pulse generation unit, a polarity of the first electrode unit is periodically changed, wherein a polarity of the second electrode unit is changed to a polarity opposite to the polarity of the first electrode unit, so that directions of lines of electric force of an electric field formed over a predetermined length range of the fuel supply pipe are periodically reversed.

2. The fuel ionization apparatus according to claim 1,
wherein, when the fuel flows from a first position toward a second position in the fuel supply pipe,
the first position is charged to a first polarity by the first electrode unit,
the second position is charged to a second polarity by the second electrode unit, and
an electric field which applies electrostatic force to the fuel is formed between the first position and the second position.

3. The fuel ionization apparatus according to claim 1,
wherein, when a first position and a second position that are separated from each other in a lengthwise direction of the fuel supply pipe are defined in order in which the fuel flows,
the first electrode unit is installed so that a first polarity is formed at the first position,
the second electrode unit is installed so that a second polarity is formed at the second position,
the pulse generation unit alternately applies positive electricity (pulse) and negative electricity (pulse) to the first electrode unit,
the pulse generation unit applies, when applying positive electricity (pulse) to the first electrode unit, negative electricity (pulse) to the second electrode unit, and
the pulse generation unit applies, when applying negative electricity (pulse) to the first electrode unit, applies positive electricity (pulse) to the second electrode unit.

4. The fuel ionization apparatus according to claim 1, further comprising:
a third electrode unit applied with electricity of a preset polarity,
wherein, when a first position, a second position and a third position that are separated from each other in a lengthwise direction of the fuel supply pipe are defined,
the first electrode unit charges the first position to a first polarity,
the second electrode unit charges the second position to a second polarity,
the third electrode unit charges the third position to a third polarity,
the first polarity and the second polarity are alternately reversed by the pulse generation unit, and
the third polarity is continuously maintained as a positive polarity or is continuously maintained as a negative polarity.

5. The fuel ionization apparatus according to claim 4,
wherein the third electrode unit charges the third position to the third polarity downstream of the first position and the second position, or charges the third position to the third polarity upstream of the first position and the second position.

6. The fuel ionization apparatus according to claim 1, wherein
the first electrode unit and the second electrode unit are installed on the fuel supply pipe, and
an insulation covering which prevents a current of each electrode unit from flowing to the fuel supply pipe is installed between each electrode unit and the fuel supply pipe.
